(19) United States
(12) Patent Application Publication
(10) Pub. No.: US 2016/0161852 A1
(43) Pub. Date: Jun. 9, 2016

(54) MIRROR FOR A MICROLITHOGRAPHIC PROJECTION EXPOSURE SYSTEM AND METHOD FOR PROCESSING A MIRROR

(71) Applicant: Carl Zeiss SMT GmbH, Oberkochen (DE)

(72) Inventors: Karl-Heinz SCHUSTER, Koenigbronn (DE); Boris BITTNER, Roth (DE); Norbert WABRA, Werneck (DE); Sonja SCHNEIDER, Oberkochen (DE); Ricarda SCHNEIDER, Zusmarshausen (DE); Hendrik WAGNER, Aalen (DE); Christian WALD, Aalen (DE); Walter PAULS, Huettlingen (DE); Holger SCHMIDT, Aalen (DE)

(21) Appl. No.: 14/904,912

(22) Filed: Jan. 13, 2016

Related U.S. Application Data
(63) Continuation of application No. PCT/EP2014/063337, filed on Jun. 25, 2014.

(30) Foreign Application Priority Data
Jun. 27, 2013 (DE) 102013212467.8
Jul. 1, 2013 (DE) 102013212780.4

(51) Int. Cl. G03F 7/20; H05G 2/00; G02B 5/08

(52) U.S. Cl. CPC G03F 7/702; G02B 5/085; G02B 5/0891; G02B 5/0816; H05G 2/008; H05G 2/003

(57) ABSTRACT

A mirror for a microlithographic projection exposure apparatus and a method for processing a mirror. The mirror includes an optically effective surface, a mirror substrate and a multiple layer system configured to reflect electromagnetic radiation with an operational wavelength of the projection exposure apparatus which is incident on the optically effective surface. The multiple layer system has a plurality of reflection layer stacks (16a, 16b, 16c, 26a, 26b), between each of which a respective separation layer (15a, 15b, 15c, 25a, 25b) is arranged. This separation layer is produced from a material which has a melting temperature that is at least 80° C. but less than 300° C.

### CROSS-REFERENCE TO RELATED APPLICATIONS

This application is a National Stage Entry of International Application No. PCT/EP2014/063337, filed on Jun. 25, 2014, entitled “Mirror For A Microlithographic Projection Exposure System And Method For Processing A Mirror,” which claims priority under 35 U.S.C. §119(a) to German Patent Application Nos. 10 2013 212 467.8, filed on Jun. 27, 2013, and to DE 10 2013 212 780.4, filed on Jul. 1, 2013. The disclosures of all three related applications are considered part of and are incorporated by reference into the disclosure of the present application in their respective entireties.

### FIELD OF THE INVENTION

The invention relates to a mirror for a microlithographic projection exposure apparatus and a method for processing a mirror.

### BACKGROUND

Microlithography is used for producing microstructured components, such as, for example, integrated circuits or liquid crystal displays (LCDs). The microlithography process is carried out in a so-called projection exposure apparatus comprising an illumination device and a projection lens. The image of a mask (=reticle) illuminated by the illumination device is in this case projected, by the projection lens, onto a substrate (e.g. a silicon wafer) coated with a light-sensitive layer (photoresist) and arranged in the image plane of the projection lens, in order to transfer the mask structure to the light-sensitive coating of the substrate.

In projection lenses designed for the extreme ultraviolet (EUV) range, that is to say at wavelengths of e.g. approximately 13 nm or approximately 7 nm, owing to lack of availability of suitable light-transmissive refractive materials, mirrors are used as optical components for the imaging process.

The EUV light is generated by an EUV light source based on a plasma excitation, in respect of which FIG. 6 shows an exemplary conventional design. This EUV light source initially has a CO₂-laser (not depicted in FIG. 6) for generating infrared radiation 306 with a wavelength of λ≈10.6 pin, which is focused by a focusing optical unit (not depicted in FIG. 6), passes through an opening 311 present in a collector mirror 310 embodied as an ellipsoid and is guided to a target material 332 (tin droplets in the example) generated by a target source 335 and fed to a plasma ignition position 330. The infrared radiation 306 heats the target material 332 situated in the plasma ignition position 330 in such a way that the latter transitions into a plasma state and emits EUV radiation. By way of example, the spectral range used by the microlithographic projection exposure apparatus can be λ≈13.5±0.5 nm. This EUV radiation is focused by way of the collector mirror 310 onto an intermediate focus IF (=“Intermediate Focus”) and enters through this intermediate focus IF into a subsequent illumination device, the edge 340 of which is merely indicated and which has a clear opening 341 for the entry of light. A light trap 320 serves to prevent the direct passage (i.e. without preceding reflection at the collector mirror 310) of the infrared radiation 306 into the illumination device.

With respect to the prior art, reference is made in merely an exemplary manner to WO 2011/069881 A1, DE 10 2012 200 454 A1, DE 10 2011 080 409 A1, US 2003/0214735 A1 and US 2005/0213199 A1.

A problem occurring during operation of a projection exposure apparatus equipped with such an EUV light source is that the target material (e.g. tin) used for transition into the plasma state leads to contamination of the collector mirror in particular, a consequence of which is that there is already a significant impairment of the reflection properties thereof after a relatively short period of operation (e.g. within a few hours). Removal of this impairment without complete replacement of e.g. the collector mirror is difficult, inter alia, to the extent that the use of e.g. aqueous solutions does not come into question in view of the vacuum conditions present, wherein, in general, damage to the reflecting layer systems present on the relevant mirror (e.g. collector mirror) is also to be avoided.

Moreover, the multiple layer systems present in the mirrors can degrade during the operation of a projection exposure apparatus on account of the radiation exposure during the operation of the projection exposure apparatus and, in particular, change in terms of the optical properties thereof such that a renewal of the coating may become necessary. Furthermore, the coatings can also be damaged by scratches, local imperfections and the like, and so a renewal of the coating may also become necessary in this case.

### SUMMARY

An object of the present invention is to provide a mirror for a microlithographic projection exposure apparatus and a method for processing a mirror, which enable quick and effective restoration of the required reflection properties after contamination.

A mirror according to the invention for a microlithographic projection exposure apparatus, wherein the mirror has an optically effective surface, comprises:
a mirror substrate, and
a multiple layer system configured to reflect electromagnetic radiation with an operational wavelength of the projection exposure apparatus which is incident on the optically effective surface;
wherein the multiple layer system has a plurality of reflection layer stacks, between each of which respective separation layers are arranged, and
wherein the respective separation layers are produced from materials which have melting temperatures that are at least 80° C. and less than 300° C.

In particular, for the purposes of “renewing” the reflection properties of a mirror of a microlithographic projection exposure apparatus in the case of the presence of contamination (which optionally, in particular, can no longer be removed to a satisfactory extent by cleaning processes either), the invention is based on the concept of implementing said mirror in such a way that the mirror is designed from a plurality (i.e. at least two) reflection layer stacks (as it were “like onion skins”), between which a separation layer with a melting temperature in the range from at least 80° C. and less than 300° C. is arranged in each case. As a result of this comparative low melting temperature (which, in particular, lies far below the melting temperatures of the remaining components of the multiple layer system), it is already possible to bring about melting of the relevant separation layer for purging the (possibly contaminated) part of the multiple layer system carried by this separation layer by way of comparatively moderate heating above the usual operating temperature of the mirrors present in the projection exposure apparatus (which typically lies at 40-50° C.). Whereas conventional Mo/Si reflection layers react with a shift in the peak wavelength and premature reflection loss as a result of crystallization processes in the case of constant heating, layer systems (MoSi₂/Si and Mo/C/Si/C) with improved thermal stability which should even be able to be used permanently up to 400° C. are also described of late.

Expressed differently, the design of the mirror according to the invention as it were enables “skinning” of the mirror by way of a comparatively moderate increase in temperature, wherein the separation layer which melted as a result of the temperature increase can be transported away without residue together with the part of the multiple layer arranged thereon (i.e. arranged in the direction of the optically effective surface), without unwanted residue remaining on the reflection layer stack situated therebelow or without this reflection layer stack being damaged.

Unlike the remaining layers typically present within the multiple layer system (which serve to prevent an impairment of the reflection or even to make reflection possible), the separation layer present in the mirror according to the invention only has the function of bringing about a purge of the contaminated part of the multiple layer system carried by the separation layer, with exposure of the part situated therebelow, which is not yet contaminated and therefore “unused”, which purge is introduced by a temperature increase beyond the melting point of the separation layer when necessary—for example if a contamination which impairs the reflection properties in a manner no longer acceptable is present.

In accordance with one embodiment, the material of the separation layer has a melting temperature of less than 200° C., in particular of less than 150° C.

In accordance with one embodiment, the separation layer has a layer thickness of at least 5 μm, in particular a layer thickness in the range from 10 μm to 100 μm, which is advantageous in view of safe manufacture of depressions or diffraction structures while avoiding unwanted damage of the multiple layer systems situated therebelow.

In accordance with one embodiment, the ratio between lateral layer extent and layer thickness is at least 1000 for the separation layer.

In accordance with one embodiment, the material of the separation layer is a metal or a metal alloy.

In accordance with one embodiment, the material of the separation layer is a eutectic. This configuration is advantageous, in particular, in that the respective separation layer has a particularly well-defined melting point and immediately transitions into the liquid state when this melting temperature is reached such that the “skinning process” employed according to the invention is completed within a relatively short period of time (e.g. typically within a few minutes) and the thermal load of the relevant mirror and of the projection exposure apparatus can be kept low overall.

However, the invention is not restricted to the production of the separation layer from a eutectic, and so, in further embodiments, use can also be made of non-eutectic alloys or else pure metals with a low melting point in the above defined range. In accordance with one embodiment, the multiple layer system has a plurality of separation layers, between which a reflection layer stack is arranged in each case.

In accordance with a further aspect, the invention also relates to a mirror for a microlithographic projection exposure apparatus, wherein the mirror has an optically effective surface, comprising
a mirror substrate; and
a multiple layer system configured to reflect electromagnetic radiation with an operational wavelength of the projection exposure apparatus which is incident on the optically effective surface;
wherein the multiple layer system has a plurality of reflection layer stacks, between each of which respective separation layers are arranged. Each separation layer runs through a phase transition from solid to liquid or from solid to gaseous in a predetermined temperature range, thereby enabling a part of the multiple layer system that is carried by this separation layer to separate from the mirror.

The predetermined temperature range, in which the separation layer enables the separation of the part of the multiple layer system carried by the separation layer from the mirror of the multiple layer system from the mirror substrate, can be selected in such a way that it lies below an admissible maximum temperature for the multiple layer system and/or the mirror substrate and above a conventional and/or admissible operating temperature for the optical element. What this ensures, firstly, is that the optical element is in a stable state during the operation and that, when the part of the multiple layer system carried by the separation layer is separated, the mirror substrate of the mirror, which is intended to continue to be used, is not destroyed and neither the detachment nor the separation is made more difficult by the detachment of the multiple layer system.

Further layers, such as diffusion barriers and/or adhesion promoting layers and/or tension imparting layers can be provided between the separation layer and reflection layer stack and between the separation layer and mirror substrate.

The separation layer can be applied by any suitable methods with which the separation layer can be deposited in a uniform and defined manner. In order to avoid temperature influences or sensitivities, the separation layer can be applied in a complete and uniform layer and, in particular, be made of a material which, under the operating conditions of the mirror, has little influence on the properties of the mirror, such as e.g. by thermal expansion.

During the course of separating the part of the multiple layer system carried by the separation layer, the whole mirror or merely the separation layer is brought to the predetermined temperature, at which the separation layer changes the properties thereof in such a way that the adherence of the multiple layer system is reduced. The temperature can be set by way of heating using appropriate suitable heating sources, such as a radiation or contact heating source. In particular, use can be made of infrared emitters, heating plates or electrical resistance heaters. Direct electrical heating by guiding current through the separation layer is also feasible.

After the predetermined temperature is set, the part of the multiple layer system above the separation layer is removed by virtue of this part e.g. being gripped by an appropriately suitable gripping tool and being detached from the mirror substrate, for example by stripping off, pulling off in the tangential direction or the like.

In order to be able to exert a defined force for pulling off or separating part of the multiple layer system carried by the separation layer, use can be made of adhesives and/or coating substances for connection with an appropriate tool, which can be arranged on the optically effective surface of the mirror for simplifying the separation or pulling off

After separating the part of the multiple layer system carried by the separation layer, the separation layer can be removed completely, to be precise following various suitable measures such as flushing with liquid or gaseous media, mechanical stripping, evaporation or a different thermal removal of the residues of the detachment layer.

In accordance with one embodiment, the separation layer is produced from a material with a melting point in the range from 80° C. to 400° C., particularly less than 300° C., more particularly less than 200° C., and more particularly less than 150° C.

In accordance with one embodiment, the multiple layer system has a plurality of such separation layers, between which a reflection layer stack is arranged in each case.

Here, in particular, these separation layers can have different melting temperatures, wherein, preferably, the relevant melting temperatures are distributed in a manner decreasing in the direction from the optically effective surface to the mirror substrate. What this achieves is that the targeted heating to above the melting temperature of a separation layer only melts the latter (and not the separation layers situated therebelow, each with a higher melting temperature), with the consequence that, below the reflection layer stack exposed by the melting, further separation layers and reflection layer stacks situated therebelow are available for subsequent, further “skinning” of the mirror.

In accordance with one embodiment, the mirror substrate has a temperature sensor arrangement. As a result of this, it is possible to support a two-dimensional, spatially resolved acquisition of the temperature distribution for assisting a temperature guidance which is as exact as possible within the meaning of heating to just above the respective melting temperature of the separation layer to be melted. Moreover, the front side (or optically effective surface) of the mirror can also be monitored using a thermal imaging camera in the form of a bolometer or a CCD camera.

In accordance with one embodiment, the multiple layer system furthermore respectively has a carrier layer between a reflection layer stack and a separation layer, which carrier layer is mechanically detachable from the mirror together with the part of the multiple layer system carried by this carrier layer. In particular, this carrier layer can have a thickness in the range from 20 μm to 200 μm and e.g. be produced from nickel (Ni). Such a carrier layer in turn enables, firstly, a residue-free exposure of the reflection layer stack situated therebelow by complete removal of the part of the multiple layer system situated over the carrier layer. Secondly, this carrier layer can also serve to provide a diffraction structure which is typically used, for example in a collector mirror within an EUV light source, for eliminating unwanted infrared radiation generated by a CO₂ laser for plasma excitation. As a result of the additional provision of the so-called carrier layer, such a diffraction structure can be provided for each “package” of reflection layer stack and separation layer and therefore be available again after exposing an unused reflection layer stack. In further embodiments, such a diffraction structure can also be worked directly into the respective separation layer.

For the mechanical detachment of the carrier layer, the latter can, in particular, have portions extending beyond the circumference of the optically effective surface or the conventional components of the multiple layer system, which portions enable mechanical (e.g. manual) gripping of the carrier layer and detachment. This detachment itself preferably takes place under a protective gas (e.g. nitrogen) atmosphere in order to avoid oxidation, in particular of the material of the separation layers which may be susceptible thereto.

In particular, the mirror can be a collector mirror of an EUV light source. However, the invention is not restricted to the application, and so, in further embodiments, a for deflection mirror in the EUV light source or in the transition between the EUV light source and the illumination device, for example, can also be configured in the manner according to the invention.

The invention furthermore relates to a microlithographic projection exposure apparatus comprising an EUV light source, an illumination device and a projection lens, wherein the projection exposure apparatus has a mirror with the features described above. The invention furthermore also relates to a method for processing a mirror of a microlithographic projection exposure apparatus.

Further embodiments of the invention can be gathered from the description and the dependent claims.

Below, the invention is explained in more detail on the basis of exemplary embodiments depicted in the attached figures

### BRIEF DESCRIPTION OF THE DRAWINGS

In detail:

FIG. 1 shows a schematic illustration for explaining the design of a mirror in accordance with a first embodiment of the invention;

FIGS. 2-5 show schematic illustrations for explaining further possible embodiments of the invention; and

FIG. 6 shows a schematic illustration for explaining the design of a conventional EUV light source.

### DETAILED DESCRIPTION

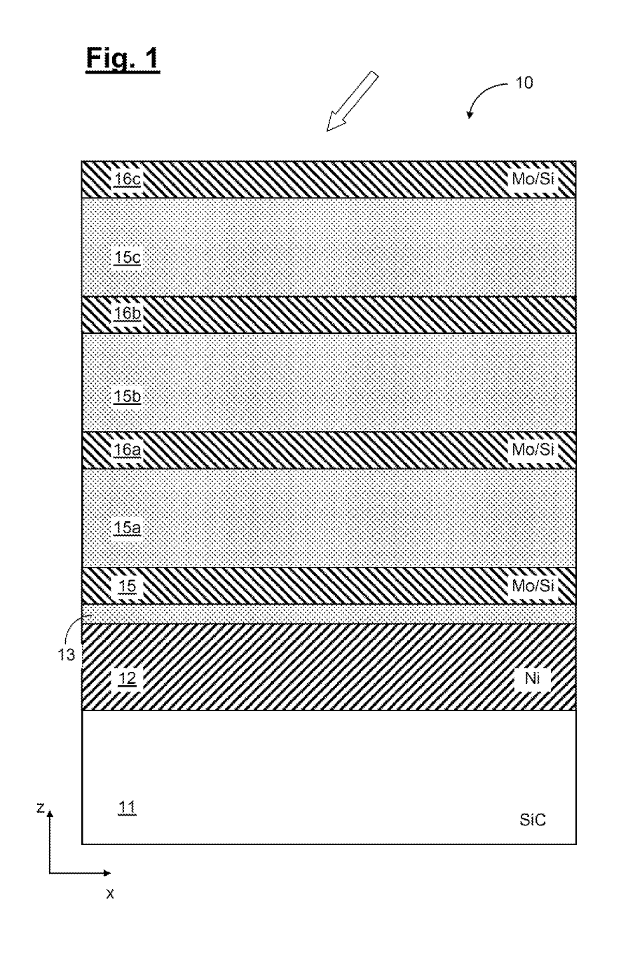

Below, an exemplary design of a mirror according to the invention in the form of a collector mirror of an EUV light source in a microlithographic projection exposure apparatus is described initially with reference to the schematic illustrations in FIG. 1.

In accordance with FIG. 1, a mirror according to the invention has, in particular, a mirror substrate 11 and a multiple layer system for reflecting EUV radiation with a wavelength of 13.5 nm incident on the optically effective surface of the mirror, wherein a carrier layer 12 (e.g. nickel; layer thickness e.g. 200 μm) and an adhesion layer 13 are arranged between the multiple layer system and the mirror substrate in the exemplary embodiment.

In accordance with FIG. 1, the multiple layer system itself has a plurality of reflection layer stacks 16a, 16b, 16c (of which merely three are depicted in an exemplary manner, the number of which, however, can in principle be arbitrary), of which each individual one has a succession of molybdenum (Mo) and silicon (Si) layers in a manner known per se and associated diffusion barrier layers, wherein, merely in an exemplary manner, the layer number within each reflection layer stack may be two hundred (without the invention being restricted thereto). Moreover, at the top, each reflection layer stack 16a, 16b, 16c has a suitable protection layer (not depicted here), e.g. made of ruthenium (Ru).

As can be seen from FIG. 1, one separation layer 15a, 15b and 15c, respectively, is arranged in each case between two respectively successive reflection layer stacks, wherein the layer thickness of the respective separation layers may lie, merely in an exemplary manner, in the range between 10 μm and 50 μm. Preferably, the separation layers 15a, 15b, 15c each have a layer thickness of more than 10 μm, which is advantageous in view of reliable manufacturing of depressions or diffraction structures while avoiding unwanted damage to the multiple layer system lying therebelow.

Exemplary embodiments for the composition of the respective separation layers 15a, 15b and 15c are listed in table 1, together with the respectively obtained value for the melting temperature (in air or in vacuo) (with the respective portions being specified in weight percent=wt %).

TABLE 1

| Separation | | Melting |
|---|---|---|
| layer | Material | temperature |
| 4 | Bismuth (Bi) 57 wt % | 78.9° C. |
| | Tin (Sn) 17 wt % | |
| | Indium (In) 26 wt % | |
| 3 | Bismuth (Bi) 52.5 wt % | 95° C. |
| | Lead (Pb) 32 wt % | |
| | Tin (Sn) 15.5 wt % | |
| 2 | Bismuth (Bi) 55.5 wt % | 124° C. |
| | Lead (Pb) 44.5 wt % | |
| 1 | Bismuth (Bi) 58 wt % | 138° C. |
| | Tin 42 wt % | |

As can be seen from table 1, the separation layers “1” to “4” are constituted in such a way in the exemplary embodiment that the respective melting temperature increases in the direction from the optically effective surface to the mirror substrate (“separation layer 1”). As a result of this, what can be achieved by targeted heating above the melting temperature of the respective top separation layer (e.g. “separation layer 4”) is that this separation layer can be melted and purged (in particular “flooded away”) together with the part of the multiple layer system situated thereabove. Hence, as it were, if the respectively exposed optically effective surface of the mirror is too strongly contaminated, a reflection layer stack situated therebelow (namely situated below the melted separation layer) can be exposed for providing a new or still unused effective surface merely by the temperature control or the targeted heat influx in a “skinning process”. In principle, the heating or heat supply required for melting the respective separation layer 15a, 15b or 15c can be brought about in any way in this case (e.g. by heat radiation, convection, etc.).

Further possible compositions of the respective separation layers are listed in table 2:

TABLE 2

| Material | Melting temperature |
|---|---|
| Tin (Sn) 62 wt % | 179° C. |
| Lead (Pb) 36 wt % | |
| Silver (Ag) 2 wt % | |
| Tin (Sn) 63 wt % | 183° C. |
| Lead (Pb) 37 wt % | |
| Tin (Sn) 96.3 wt % | 221° C. |
| Silver (Ag) 3.7 wt % | |
| Tin (Sn) 99.3 wt % | 227° C. |
| Copper (Cu) 0.7 wt % | |
| Gold (Au) 80 wt % | 280° C. |
| Tin (Sn) 20 wt % | |
| Indium (In) | 156.17° C. |
| Tin (Sn) | 231.91° C. |
| Bismuth (Bi) | 271.3° C. |
| Lead (Pb) | 327.43° C. |
| Zinc (Zn) | 419.4° C. |

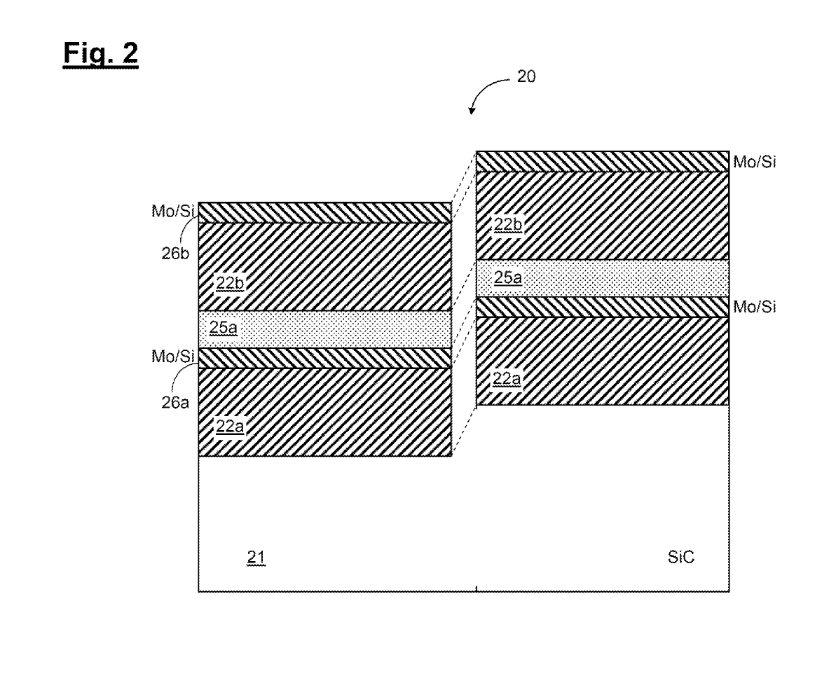

FIG. 2 serves as a schematic illustration for explaining the possible design of a mirror according to the invention in a further embodiment. In particular, this embodiment differs from the one from FIG. 1 in that an additional carrier layer 22b (made of nickel and with a typical layer thickness in the range from 20 μm to 200 μm in the exemplary embodiment) is respectively provided between a reflection layer stack 26b and a separation layer 25a.

This carrier layer 22b firstly enables the introduction of a diffraction structure (indicated in FIG. 2 by a step) serving to eliminate unwanted light components (e.g. infrared light generated in an EUV light source), which can therefore be provided anew for each “new package” made of reflection layer stack and separation layer after melting the separation layer situated thereabove. Secondly, this carrier layer 22b also enables a mechanical detachment of the whole part of the multiple layer system carried by said carrier layer 22b for the purposes of exposing the reflection layer stack situated therebelow.

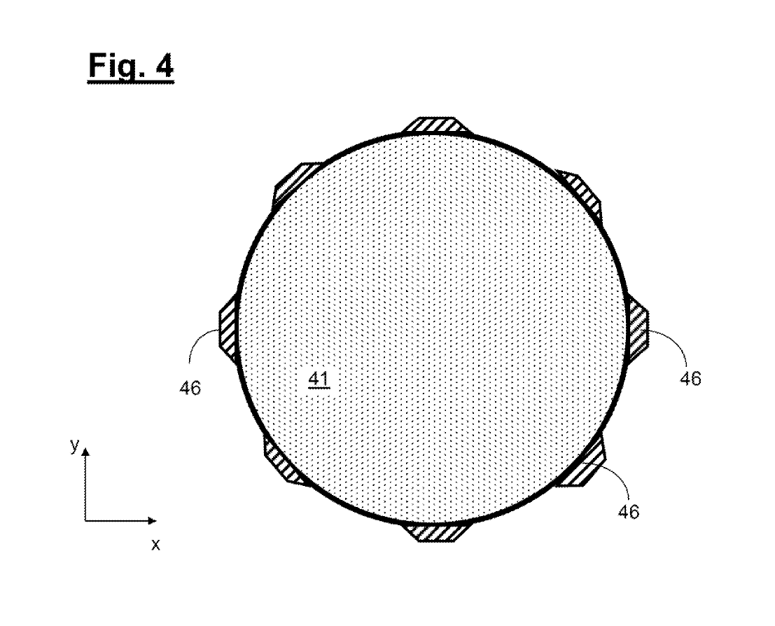

For simplifying a mechanical detachment to be carried out (in particular manually in a protective gas atmosphere, e.g. in nitrogen or argon), the carrier layer can have portions 46 projecting beyond the mechanically or optically used diameter of the mirror, as indicated schematically in FIG. 4. In practice, the evaporation or deposition of the individual carrier layers 22b can take place using masks, and so the respective carrier layer for each individual layer package is generated locally in an enlarged manner in the relevant circumferential region.

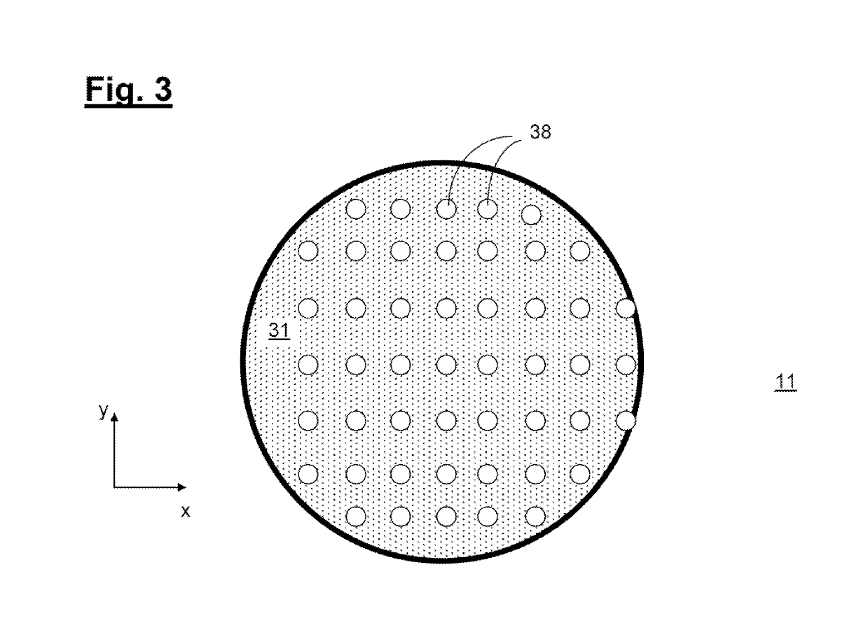

In accordance with FIG. 3, the mirror substrate 31 can have a temperature sensor arrangement 38. As a result of this, it is possible to support a two-dimensional, spatially resolved acquisition of the temperature distribution for assisting a temperature guidance which is as exact as possible within the meaning of heating to just above the respective melting temperature of the separation layer to be melted. Moreover, the front side (or optically effective surface) of the mirror can also be monitored using a thermal imaging camera in the form of a bolometer or a CCD camera.

The “skinning process” according to the invention or removal of the (e.g. contaminated) part of the multiple layer system situated above the melted separation layer can additionally be assisted by virtue of the liquefied separation layer material being guided over the relevant surface and, in the process, the “used up” part of the multiple layer system to be guided away being flooded away by the flow and, in the process, exposing the reflection layer stack situated therebelow.

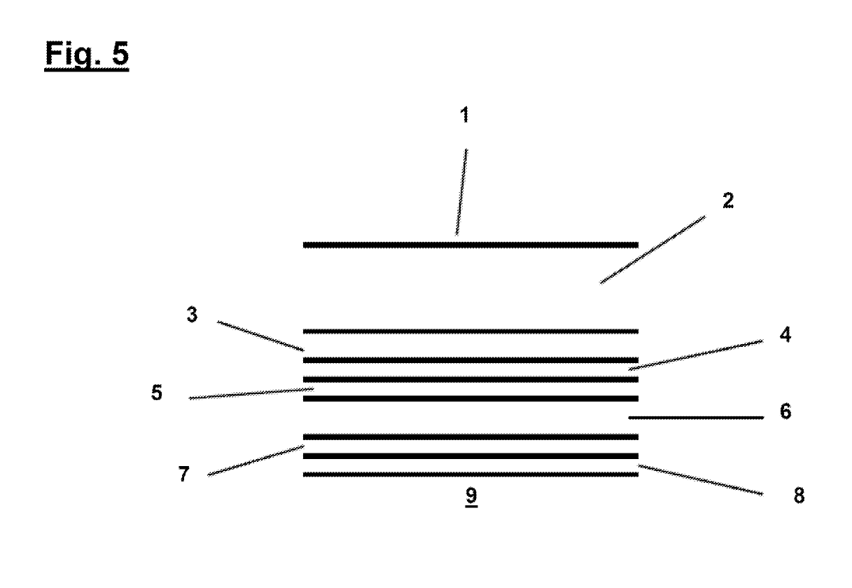

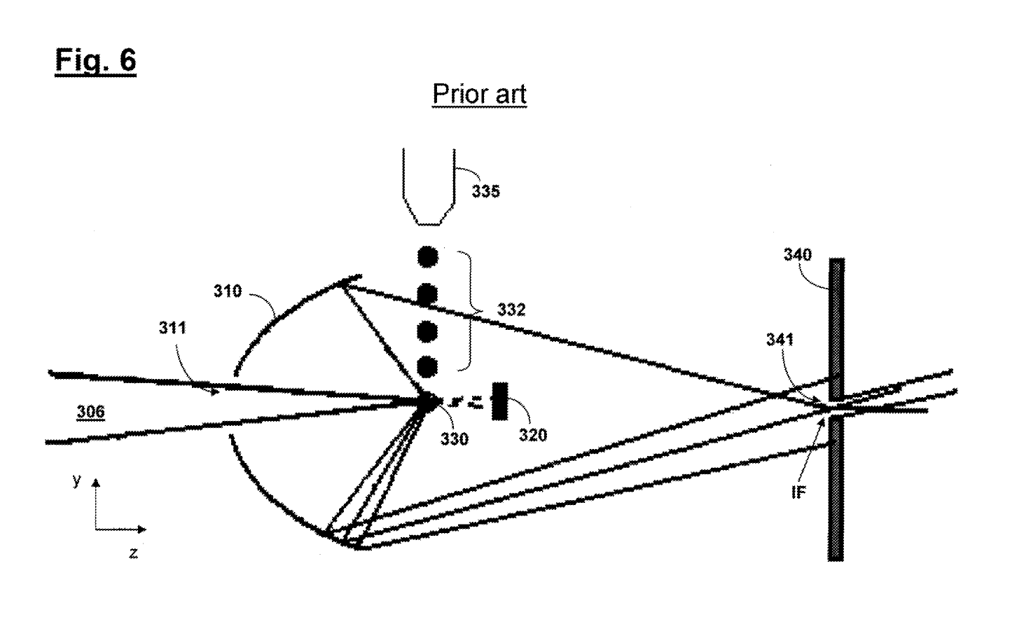

FIG. 5 shows a schematic illustration for explaining a possible design of a mirror in accordance with a further embodiment of the invention. A corresponding mirror has a main body or a mirror substrate 9, which, for example, is made from a material with a low thermal expansion, such as the ULE (registered trademark of Corning) or Zerodur (trademark of Schott AG) material, for example. The mirror furthermore has a coating in the form of a reflection layer stack 2 (e.g. made of alternating molybdenum and silicon layers) for reflecting electromagnetic radiation with an operational wavelength of the projection exposure apparatus which is incident on the optically effective surface.

A detachment layer or separation layer 6 in accordance with the invention is formed between the reflection layer stack 2 and the mirror substrate 9, which enables the separation of the reflection layer stack 2 from the mirror substrate 9 if the reflection layer stack 2 or the part of the multiple layer system carried by the separation layer 6 needs to be replaced.

Additional layers are provided in the shown exemplary embodiment; however, these can be omitted in certain circumstances. Furthermore, further layers, which are not shown here, can be provided above or below the reflection layer stack 2 or as a component of the reflection layer stack 2.

By way of example, a cap layer, e.g. made of Ru, Rh, Si₃N₄, or a radiation protection layer (e.g. made of NiSi) may also be present.

As additional layers, a diffusion barrier 8 and an adhesion promoting layer 7 can be provided between the separation layer 6 and the mirror substrate 9 and an adhesion promoting layer 5 and a diffusion barrier 4 can be provided between the separation layer 6 and the reflection layer stack 2, as indicated schematically in FIG. 5. Additionally, a tension imparting layer 3, which is arranged between the diffusion barrier 4 and the reflection layer stack 2 in the present exemplary embodiment, can be provided between the separation layer 6 and the reflection layer stack 2. In further embodiments, the various sub-layers, such as adhesion imparting layers 7, 5 and diffusion barriers 4, 8 and the tension imparting layer 3 can also be provided in a different sequence or be (possibly partially) omitted.

As soon as a reflection layer stack 2 or the part of the multiple layer system carried by the separation layer 6 is intended to be separated from the mirror substrate 9, the mirror overall or, specifically, the separation layer 6 is brought to a predetermined temperature, which renders it possible to separate the part of the multiple layer system carried by the separation layer from the mirror substrate 9 by virtue of a separation occurring within the separation layer 6 or at an interface of the separation layer 6, i.e. the interface to the adhesion promoting layer 5 or to the adhesion promoting layer 7.

In one exemplary embodiment, the separation layer 6 can be brought to the temperature at which the separation layer transitions from a solid into a liquid state such that the layers lying thereabove and, in particular, the reflection layer stack 2, can be wiped away by a cleaning cloth or pulled off using an appropriate gripping tool. In particular, the pulling-off direction can be tangential to the surface as shearing forces usually lead more easily to detachment than pulling forces which have to act against adhesion forces. For an easier grip on the coating to be detached, the optically effective surface 1 can be provided with adhesive strips, other adhesive means or a coating.

The separation layer 6 can also be evaporated such that a separation of the layers situated thereabove is implemented in this manner.

After detaching the part of the multiple layer system carried by the separation layer 6 and, optionally, layers lying between the separation layer 6 and the reflection layer stack 2, such as the tension imparting layer 3, diffusion barrier 4 and adhesion promoting layer 5, the remainder of the separation layer 6 is removed completely, for example by a suitable flushing in the liquid or gaseous medium or by a thermal processing, in which corresponding residues can be evaporated. Moreover, it is also possible to use mechanical or wet-chemical methods for removing the separation layer 6.

Then, this can be followed by surface processing of the remaining layers or of the mirror substrate 9, for example by ion beam processing and renewed coating.

By way of example, the so-called Field's metal, which comprises e.g. approximately 51% by weight of indium, 32.5% by weight of bismuth and 16.5% by weight of tin and the melting temperature of which lies at 62° C., can be used as a separation layer 6. As a further alternative, use can be made of e.g. Rose's metal, which has 50% by weight of bismuth, 25% by weight of lead and 25% by weight of tin and has a melting temperature of 98° C. In the case of such detachment layers, use can be made of e.g. boron carbide as a diffusion barrier in relation to a mirror substrate made of ULE or Zerodur.

The aforementioned materials for the separation layer 6 can be used, in particular, in mirrors and projection lenses as the melting temperatures of the aforementioned alloys lie above the operating temperature of a mirror in the projection lens but significantly below the corresponding melting temperatures of the reflection layer stack 2. The operating temperatures can be significantly higher for mirrors which are used in the illumination device of a projection exposure apparatus or as a collector, and so e.g. brass solder or other solders, in particular brazing solders, whose melting temperature lies in the region from 800° C. to 1000° C., can be used there as a separation or detachment layer. It is therefore possible, depending on the case of application, to determine the appropriate materials for the detachment layer.

The separation layer 6, which is preferably arranged over the whole or part of the optically effective surface, can be applied with a thickness in the range from a few nanometers to some micrometers.

Even though the invention has been described on the basis of specific embodiments, numerous variations and alternative embodiments are evident to the person skilled in the art, e.g. through combination and/or exchange of features of individual embodiments. Accordingly, it is understood for the person skilled in the art that such variations and alternative embodiments are concomitantly encompassed by the present invention, and the scope of the invention is restricted only within the meaning of the accompanying patent claims and the equivalents thereof.

1.-19. (canceled)

20. A mirror for a microlithographic projection exposure apparatus, wherein the mirror has an optically effective surface, comprising:
a mirror substrate; and
a multiple layer system configured to reflect electromagnetic radiation with an operational wavelength of the projection exposure apparatus which is incident on the optically effective surface;
wherein the multiple layer system has a plurality of reflection layer stacks, between each of which a respective separation layer is arranged;
wherein each respective separation layer is produced from a material which has a melting temperature that is at least 80° C. and is less than 300° C.; and
wherein the separation layer has a layer thickness of at least 5 μm.

21. The mirror as claimed in claim 20, wherein the material of the separation layer has a melting temperature of less than 150° C.

22. The mirror as claimed in claim 20, wherein the separation layer has a layer thickness between 10 μm and 100 μm.

23. The mirror as claimed in claim 20, wherein the separation layer extends laterally by a value that is at least 1000 times as great as a maximum thickness value for the separation layer.

24. The mirror as claimed in claim 20, wherein the separation layer is composed of a metal or a metal alloy.

25. The mirror as claimed in claim 20, wherein the separation layer is composed of a eutectic.

26. The mirror as claimed in claim 20, wherein the separation layer comprises at least one constituent selected from the group consisting of bismuth (Bi), indium (In), tin (Sn), lead (Pb), copper (Cu), antimony (Sb), cadmium (Cd), silver (Ag), gold (Au), zinc (Zn) and gallium (Ga).

27. The mirror as claimed in claim 20, wherein the multiple layer system has a plurality of separation layers between which respective reflection layer stacks are respectively arranged.

28. A mirror for a microlithographic projection exposure apparatus, wherein the mirror has an optically effective surface, comprising:
a mirror substrate; and
a multiple layer system configured to reflect electromagnetic radiation with an operational wavelength of the projection exposure apparatus which is incident on the optically effective surface;
wherein the multiple layer system has a plurality of reflection layer stacks, between each of which a respective separation layer is arranged, which separation layer runs through a phase transition from solid to liquid or from solid to gaseous in a predetermined temperature range, thereby enabling a part of the multiple layer system that is carried by the separation layer that has run through the phase transition to separate from the mirror.

29. The mirror as claimed in claim 28, wherein the multiple layer system comprises a plurality of the separation layers, between each of which a respective one of the reflection layer stacks is arranged.

30. The mirror as claimed in claim 29, wherein the separation layers each have mutually differing melting temperatures.

31. The mirror as claimed in claim 30, wherein the mutually differing melting temperatures of the separation layers increase from a first of the separation layers, which is disposed closest to the optically effective surface, to a final one of the separation layers, which is disposed closest to the mirror substrate.

32. The mirror as claimed in claim 28, wherein the separation layer is produced from a material with a melting point between 80° C. and 400° C.

33. The mirror as claimed in claim 28, wherein the multiple layer system further comprises a carrier layer between a reflection layer stack and a separation layer, which carrier layer is configured to mechanically detach from the mirror together with the part of the multiple layer system that is carried by the carrier layer.

34. The mirror as claimed in claim 33, wherein the carrier layer has a thickness between 20 μm and 200 μm.

35. The mirror as claimed in claim 20, wherein the mirror substrate comprises a temperature sensor arrangement.

36. The mirror as claimed in claim 20, wherein the mirror is a collector mirror of an extreme ultraviolet (EUV) light source.

37. A microlithographic projection exposure apparatus comprising an EUV light source, an illumination device and a projection lens, wherein the projection exposure apparatus comprises a mirror as claimed in claim 20.

38. A method for processing a mirror of a microlithographic projection exposure apparatus, comprising:
providing a mirror comprising a mirror substrate and a multiple layer system configured to reflect electromagnetic radiation at an operating wavelength of the projection exposure apparatus which is incident on the optically effective surface, wherein the multiple layer system has a plurality of reflection layer stacks, between which separation layers are respectively arranged, and
melting at least one of the separation layers for separating a part of the multiple layer system that is carried by the one separation layer from the mirror.

39. The mirror as claimed in claim 26, wherein the separation layer comprises an alloy of at least two constituents selected from the group consisting of bismuth (Bi), indium (In), tin (Sn), lead (Pb), copper (Cu), antimony (Sb), cadmium (Cd), silver (Ag), gold (Au), zinc (Zn) and gallium (Ga).

40. The mirror as claimed in claim 32, wherein the separation layer is produced from a material with a melting point between 80° C. and 200° C.
